(19) United States
(12) Patent Application Publication
(10) Pub. No.: US 2018/0358533 A1
(43) Pub. Date: Dec. 13, 2018

(54) THERMOELECTRIC DEVICE

(71) Applicant: Mahle International GmbH, Stuttgart (DE)

(72) Inventors: Thomas Himmer, Reichenbach (DE); Michael Moser, Ellwangen (DE)

(73) Assignee: Mahle International GmbH, Stuttgart (DE)

(21) Appl. No.: 16/060,926

(22) PCT Filed: Dec. 6, 2016
(86) PCT No.: PCT/EP2016/079949

§ 371 Date: Jun. 8, 2018

(30) Foreign Application Priority Data
Dec. 9, 2015 (DE) 10 2015 224 710.4

(51) Int. Cl. H01L 35/30; F28D 7/00; F28F 1/32; H01L 35/32

(52) U.S. Cl. CPC H01L 35/30; F28D 7/0083; F28D 7/0025; H01L 35/325; F28F 1/32

(57) ABSTRACT

A thermoelectric device may include a plurality of thermoelectric modules each having a plurality of thermoelectric elements. The device may also include a plurality of elongated first sheet-metal shaped parts thermally coupling the plurality of thermoelectric modules to two first fluid lines. The plurality of first sheet-metal shaped parts may be thermally and mechanically coupled to the plurality of thermoelectric modules. The device may further include a plurality of elongated second sheet-metal shaped parts thermally coupling the plurality of thermoelectric modules to two second fluid lines. Each of the first sheet-metal shaped parts and each of the second sheet-metal shaped parts may have a respective main section. The respective main section may transition into a respective end section at two respective longitudinal ends. The respective end section may be thermally and mechanically connected to an associated fluid line of the two first fluid lines and the two second fluid lines.

### CROSS-REFERENCE TO RELATED APPLICATIONS

This application claims priority to International Patent Application No. PCT/EP2016/079949, filed on Dec. 6, 2016 and German Patent Application No. DE 10 2015 224 710.4, filed on Dec. 9, 2015, the contents of both of which are hereby incorporated by reference in their entirety.

### TECHNICAL FIELD

The invention relates to a thermoelectric device, in particular a thermoelectric generator.

### BACKGROUND

The term “thermoelectricity” is understood to be the mutual influencing of temperature and electricity and its conversion into one another. Thermoelectric elements utilize this influence in order to generate electric energy as thermoelectric generators. Thermoelectric generators convert temperature differences into an electric potential difference, thus into an electric voltage. A heat flow can be converted into an electric current through this. Such thermoelectric modules can be used for example for the recovery of waste heat, for example in the case of an internal combustion engine. Compared to a surrounding area or compared to a coolant, excess waste heat has, for example, a temperature difference, whereby a heat flow can be generated, which can be converted into an electric current with the help of such thermoelectric modules, which corresponds to said waste heat recovery.

A thermoelectric module typically has a plurality of thermoelectric elements in the form of positively and negatively doped semiconductor materials, which are electrically interconnected via a plurality of conductor links. On its cold side, the thermoelectric module has an outer wall, which can be identified as cold side wall, and which is connected to a plurality of cold-side conductor links in a heat-conducting, electrically insulated and firm manner. On its warm side, the thermoelectric module analogously has an outer wall, which forms a warm side, which is connected to a plurality of warm-side conductor links in a heat-conducting, electrically insulated and firm manner. The thermoelectric elements are thereby arranged between cold side wall and warm side wall, so that they extend between the cold-side and warm-side conductor links.

Such a thermoelectric module is known for example from DE 1 539 322 A.

It is also known from the prior art to stack a plurality of thermoelectric modules one atop the other, so as to improve the efficiency of the thermoelectric device in this way.

### SUMMARY

It is an object of the present invention to specify new ways in the development of thermoelectric devices, in particular when they are realized as thermoelectric generator.

This object is solved by means of the subject matter of the independent patent claim(s). Preferred embodiments are the subject matter of the dependent patent claim(s).

It is thus the basic idea of the invention to stack the individual thermoelectric modules of the thermoelectric device, in which the thermoelectric elements are present, one atop the other and to arrange a first or second sheet-metal shaped part, which serves as thermal contact to a first or second fluid line, respectively, between two adjacent modules. A so-called hot medium can thereby flow through the first fluid line and a so-called cold medium can flow through the second fluid line, or vice versa. In the case at hand, the terms “hot medium” and “cold medium” are understood to be two fluids of a different temperature, wherein one of the two fluids, the hot medium, has a higher temperature than the other fluid, the cold medium. The thermoelectric modules are thus coupled to the two fluids of a different temperature via the first or second sheet-metal shaped parts, respectively. The temperature difference, which is present between the two fluids, is thereby transferred by means of the sheet-metal shaped parts into the thermoelectric modules, which, following the operating principle of a thermoelectric generator, can generate an electric potential difference, thus an electric voltage, from the temperature difference.

According to the invention, the second sheet-metal shaped parts now extend perpendicular to the first sheet-metal shaped parts. This allows for an arrangement of the first and second fluid lines with the hot or cold medium, respectively, at a slight distance to the thermoelectric modules. This, in turn, results in an improved thermal coupling of the thermoelectric modules to the hot or cold medium, respectively, in the fluid lines, which is associated with an improved efficiency of the thermoelectric device. In addition, the installation space required for the thermoelectric device can be kept small by means of the arrangement of the first and second sheet-metal shaped parts perpendicular to one another as presented herein.

A thermoelectric device according to the invention comprises a number of thermoelectric modules, which are stacked one atop the other along a stacking direction and each have multiple thermoelectric elements. The thermoelectric device further comprises a number of elongate first sheet-metal shaped parts, which extend along a first direction of longitudinal extent and thermally couple the thermoelectric modules to two first fluid lines. The first sheet-metal shaped parts are thermally and mechanically coupled to the thermoelectric modules. The thermoelectric device furthermore comprises a number of elongate second sheet-metal shaped parts, which extend along a second direction of longitudinal extent, which runs perpendicular to the first direction of longitudinal extent. The second sheet-metal shaped parts thermally couple the thermoelectric modules to two second fluid lines. The first and second sheet-metal shaped parts each have a main section which, at the longitudinal ends of the sheet-metal shaped parts, transitions into a respective end section, which, in turn, is thermally and mechanically connected to the associated fluid line.

In a preferred embodiment, the end section is embodied as collar section, which sticks out from the main section at an angle. This measure allows for a flat fastening of the sheet-metal shaped parts to the fluid lines.

Advantageously, the collar sections can extend along the stacking direction. Particularly advantageously, the collar section sticks out from the main section at a right angle. Both measures simplify the attaching of the sheet-metal shaped parts to the fluid lines.

In a further preferred embodiment, either a first sheet-metal shaped part, which is mechanically and thermally connected to at least one first fluid line, is arranged in the stacking direction between two adjacent thermoelectric modules, or a second sheet-metal shaped part is arranged, which is mechanically and thermally connected to at least one fluid line. It is ensured in this way that each thermoelectric module is thermally connected to the two first as well as to the two second fluid lines.

In an advantageous further development, two first sheet-metal shaped parts and/or two second sheet-metal shaped parts are arranged in the stacking direction between two adjacent thermoelectric modules. This measure leads to an improved thermal contact of the hot or cold side, respectively, of the thermoelectric module with the respective fluid line.

Particularly advantageously, the two first and/or second sheet-metal shaped parts lie flat against one another in the area of their main sections. This measure increases the stiffness of the thermoelectric device.

Advantageously, the collar sections of the two first and/or second sheet-metal shaped parts stick out from the main section in the opposite direction.

In another advantageous further development, an intermediate layer or an intermediate film, preferably of an elastic material, most preferably of graphite, is arranged between the two first sheet-metal shaped parts and/or two second sheet-metal shaped parts. Said intermediate layer could serve as “heat spreader” and simultaneously ensures an improved pressure distribution in the two sheet-metal shaped parts, which lie against one another.

A particularly stable mechanical fastening of the sheet-metal shaped parts to the fluid lines with a simultaneous high thermal coupling is attained, when at least one sheet-metal shaped part is fastened to at least one fluid line by means of an integral connection, preferably by means of a solder connection.

In an advantageous further development, at least one sheet-metal shaped part is fastened to at least one fluid line by means of a thermally conducting layer or film, in particular by means of a layer or film of graphite. This measure effects an improved thermal contact between the sheet-metal shaped part and the fluid lines. In the case of this variation, sheet-metal shaped part and fluid line are pressed with one another, for the purpose of which provision can be made on the fluid line for a suitable pressure generating device, in particular in the form of a tightening strap.

In another preferred embodiment, the end section is embodied as engagement section, which lengthens the main section in its direction of longitudinal extent and engages through an aperture provided in the fluid line. In the case of this variation, the engagement section/end section protrudes into a line interior of the fluid line. This provides for a particularly good securing of the sheet-metal shaped parts to the fluid lines.

A stable mechanical fastening of the sheet-metal shaped parts to the fluid lines with a simultaneous high thermal coupling is also attained in that the sheet-metal shaped part is connected to the respective fluid line in the area of the aperture by means of an integral connection, preferably by means of a solder connection.

In the transition area between the main section and the end section, the sheet-metal shaped part particularly advantageously has a bead, which is arranged outside of the line interior and which acts as stop on the sheet-metal shaped part. This measure facilitates the positioning of the sheet-metal shaped parts at the fluid lines in the course of the assembly of the thermoelectric device. The beads also ensure an enlarged contact surface in response to the soldering of the sheet-metal shaped parts with the fluid lines.

In a further advantageous further development, provision is made in the engagement section of the sheet-metal shaped part, which protrudes into the line interior, for at least one passage opening, preferably for a number of passage openings. The at least one passage opening serves the purpose of improving the heat transition between fluid and sheet-metal shaped part and simultaneously ensure a pressure drop, which is small at best, in the fluid, which flows through the fluid line and which strikes the engagement section.

In a further preferred embodiment, at least one fluid line is embodied in at least two parts with a line bottom and a line cover. This is preferably the case for all fluid lines. This measure facilitates the mounting of the fluid lines. For reinforcing purposes, a rib structure for reinforcing the fluid line, which is supported on the line bottom as well as on the line cover, is arranged in the at least one two-part fluid line.

The two first fluid lines and the two second fluid lines preferably each extend along the stacking direction. An essentially unlimited number of thermoelectric modules can be stacked one atop the other and can be coupled to the fluid lines in this way.

Particularly advantageously, a first heat conducting element and a second sheet-metal shaped part alternate along the stacking direction. This provides for the operationally required coupling of the thermoelectric modules to the first as well as to the second heat reservoir in a structurally particularly simple manner.

An advantageous further development of the invention, in which the sheet-metal shaped parts each have to longitudinal sides and two transverse sides, turns out to be particularly installation space-saving. In the case of this variation, a longitudinal side of a first heat conducting element extends perpendicular to the longitudinal side of a second heat conducting element.

In a further preferred embodiment, the two first fluid lines are arranged on the two longitudinal ends of the first sheet-metal shaped parts. The two second fluid lines are accordingly arranged on the two longitudinal ends of the second sheet-metal shaped parts. This variation also requires particularly little installation space.

In the cross section vertically to the stacking direction, the two first fluid lines are particularly preferably arranged substantially offset by 90° to the two second fluid lines. The installation space required for the thermoelectric device in the lateral direction, thus orthogonally to the stacking direction, can be kept particularly small in this way.

In the cross section vertically to the stacking direction, the fluid lines can advantageously each substantially have the geometry of a rectangle. Along its longitudinal side, a respective first or second fluid line is thereby arranged on a transverse side of the respective heat conducting element. This measure provides for a large contact surface between the heat conducting elements and the fluid lines to ensure a highly effective thermal contact.

A particularly good mechanical fastening of the heat conducting elements to the thermoelectric modules is attained when the heat conducting elements form a press-fit with the thermoelectric modules.

In the cross section vertically to the stacking direction, the thermoelectric modules can particularly advantageously have substantially the geometry of a square. The 90° rotational symmetry associated therewith allows for the production of the first and second heat conducting elements as identical parts. This leads to a reduction of the production costs of the thermoelectric device.

In an advantageous further development, the first heat reservoir has two first fluid lines, through which a hot medium can flow, and which are located opposite one another in the cross section vertically to the stacking direction and which are arranged on the two longitudinal ends of the first heat conducting elements. In the alternative or in addition, the second heat reservoir has two second fluid lines, through which a cold medium can flow, and which are located opposite one another in the cross section vertically to the stacking direction and which are arranged on the two longitudinal ends of the second heat conducting elements.

In the cross section vertically to the stacking direction, the fluid lines can advantageously substantially have the geometry of a rectangle. Along its longitudinal side, a respective first or second fluid line is thereby arranged on a transverse side of the respective sheet-metal shaped part. This measure provides for a large contact surface between the heat conducting elements and the fluid lines to ensure a highly effective thermal contact.

A particularly stable fastening of the thermoelectric modules on the sheet-metal shaped parts is attained when they form a press-fit with the heat conducting elements.

In the top view along the stacking direction, the thermoelectric modules can advantageously substantially have the geometry of a square.

In a further advantageous further development, at least a first and/or second fluid line is embodied as three-part flat pipe comprising a first and a second part, which, together, form an outer structure, which defines an interior of the flat pipe. In this further development, a third part of the flat pipe forms a rib-like inner structure, which divides the interior into multiple fluid channels and which is supported on the outer structure to reinforce the flat pipe. By dividing the interior into multiple fluid channels, the thermal interaction of the first or second fluid, respectively, with the thermoelectric modules can be improved. The rib structure simultaneously effects an improved mechanical reinforcement of the flat pipe.

In another advantageous further development, at least a first and/or second fluid line is embodied as two-part flat pipe comprising a first and a second part, which, together, form an outer structure, which defines an interior of the flat pipe. In this embodiment, a third part of the flat pipe forms a rib-like inner structure, which divides the interior into multiple fluid channels and which is supported on the outer structure to reinforce the flat pipe. The third part is hereby integrally molded on the second part, thus resulting in a two-part formation of the flat pipe. By dividing the interior into multiple fluid channels, the thermal interaction of the first or second fluid, respectively, with the thermoelectric modules can be improved. The rib structure simultaneously effects an improved mechanical reinforcement of the flat pipe. The two-part formation of the flat pipe is thereby associates with particularly low production costs.

Further important features and advantages of the invention follow from the subclaims, from the drawings, and from the corresponding figure description by means of the drawings.

It goes without saying that the above-mentioned features and the features, which will be described below, cannot only be used in the respective specified combination, but also in other combinations or alone, without leaving the scope of the present invention.

Preferred exemplary embodiments of the invention are illustrated in the drawings and will be described in more detail in the description below, whereby identical reference numerals refer to identical or similar or functionally identical components.

### BRIEF DESCRIPTION OF THE DRAWINGS

In each case schematically:

FIG. 1 shows an example a thermoelectric device according to the invention in a longitudinal section along its stacking direction,

FIG. 2 shows the thermoelectric device of FIG. 1 in a cross section vertically to the stacking direction and along the sectional line II-II of FIG. 1,

FIG. 3 shows a first variation of the thermoelectric device of FIG. 1,

FIG. 4 shows a detailed illustration of the thermoelectric device of FIG. 3 in the area of its fluid line and in the cross section vertically to the stacking direction,

FIG. 5 shows a second variation of the thermoelectric device of FIG. 1,

FIG. 6 shows a third variation of the thermoelectric device of FIG. 1,

FIG. 7 shows a first further development of the first or second fluid lines, respectively,

FIG. 8 shows a second further development of the first or second fluid lines, respectively.

### DETAILED DESCRIPTION

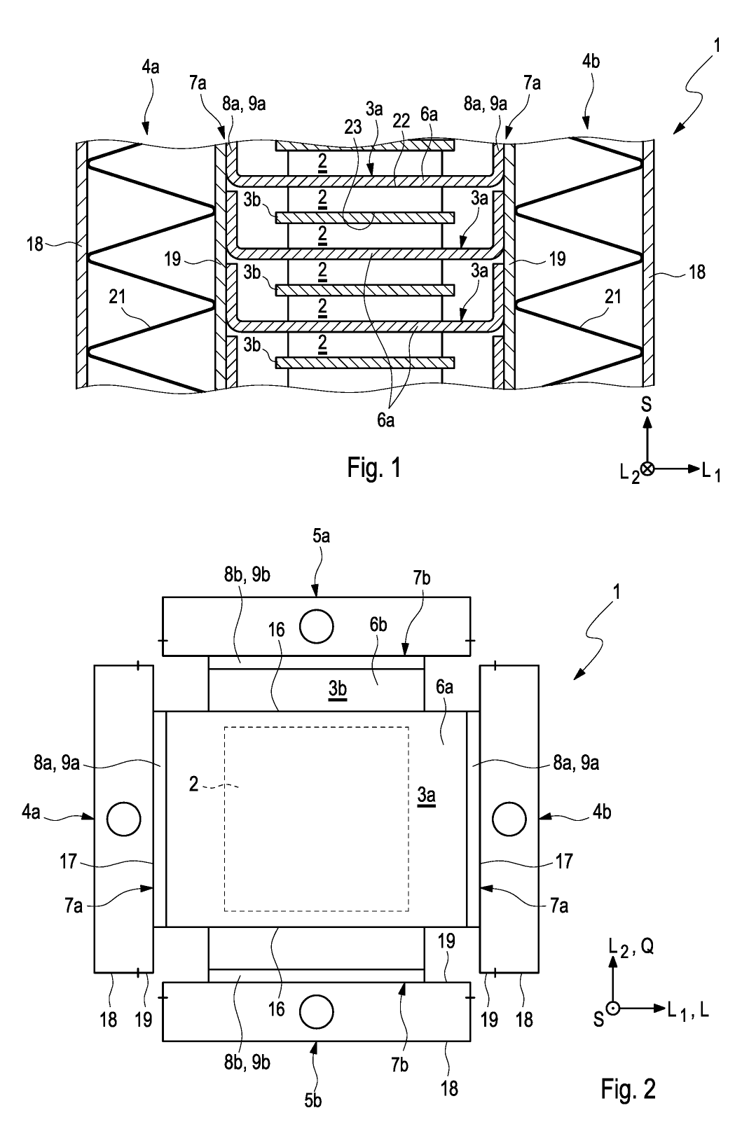

FIG. 1 illustrates an example of a thermoelectric device 1 according to the invention. The thermoelectric device 1 comprises a number of thermoelectric modules 2, which are stacked one atop the other along a stacking direction S and each have multiple thermoelectric elements (not shown in the Figures). FIG. 1 thereby shows the thermoelectric device 1 in a longitudinal section along its stacking direction S. FIG. 2 shows the thermoelectric device 1 in a cross section vertically to the stacking direction S.

As can be seen in FIGS. 1 and 2, the thermoelectric device 1 has a number of elongate first sheet-metal shaped parts 3a, which extend along a first direction of longitudinal extent L1. “Elongate” is to thereby be understood such that a length of the sheet-metal shaped part is larger than a width of the sheet-metal shaped part. The first sheet-metal shaped parts 3a are thermally and mechanically coupled to the thermoelectric modules 2 and thermally couple the thermoelectric modules 2 to two first fluid lines 4a, 4b. The thermoelectric device 1 furthermore comprises a number of elongate second sheet-metal shaped parts 3b, which extend along a second direction of longitudinal extent L₂. The second direction of longitudinal extent L₂ thereby runs perpendicular to the first direction of longitudinal extent L₁. The second sheet-metal shaped parts 3b are also thermally and mechanically coupled to the thermoelectric modules 2 and thermally couple the thermoelectric modules 2 to two second fluid lines 5a, 5b. The first as well as the second fluid lines can have line housings, which are only suggested schematically in the Figures, which act as limitation for a fluid, which flows through the respective fluid line 4a, 4b, 5a, 5b.

A hot medium, which has a higher temperature than a cold medium, which can flow through the two second fluid lines 5a, 5b, can flow through the first fluid lines 4a, 4b. Either a first sheet-metal shaped part 3a or a second sheet-metal shaped part 3b is arranged along the stacking direction S between two adjacent thermoelectric modules 2. A first sheet-metal shaped part 3a and a second sheet-metal shaped part 3b thereby alternate along the stacking direction S. The thermoelectric modules 2 thus lie against a first sheet-metal shaped part 3a with their hot side 22 and against a second sheet-metal shaped part 3b with their cold side 23.

The first sheet-metal shaped parts 3a each have a main section 6a, which, at the longitudinal ends 7a of the first sheet-metal shaped parts 3a, transitions into a respective end section 8a. This end section 8a is thermally and mechanically connected to the assigned first fluid line 4a, 4b. The hot sides 22 of the thermoelectric modules 2 are thus connected to the hot medium via the first sheet-metal shaped parts 3a. The cold sides 23 of the thermoelectric modules 2 are accordingly connected to the cold medium via the second sheet-metal shaped parts 3b.

The second sheet-metal shaped parts 3b each have a main section 6b, which, at the longitudinal ends 7b of the second sheet-metal shaped parts 3b, transitions into a respective end section 8b. The two end sections 8b are thermally and mechanically connected to their assigned second fluid lines 5a, 5b. The second sheet-metal shaped parts 3b each have a main section 6b, which, on the longitudinal ends 7b of the second sheet-metal shaped parts 3b, transitions into a respective end section 8b. The two end sections 8b are thermally and mechanically connected to the assigned second fluid lines 5a, 5b. In the example of FIGS. 1 and 2, the end sections 8a, 8b are embodied as collar sections 9a, 9b, which stick out from the main section 6a, 6b at an angle.

As can be seen in FIGS. 1 and 2, the collar sections 9a, 9b preferably extend along the stacking direction S, i.e. the collar sections 9a, 9b stick out from the respective main section 8a, 8b at a right angle. The first and second sheet-metal shaped parts 3a, 3b are fastened to the first or second fluid lines 4a, 4b, 5a, 5b, respectively, by means of an integral connection, preferably by means of a solder connection. In the alternative, the sheet-metal shaped parts 3a, 3b can be fastened to the fluid lines 4a, 4b, 5a, 5b by means of a thermally conductive layer or film (not shown), in particular by means of a layer or film of graphite. The first and second fluid lines 4a, 4b are each embodied with a line bottom 18 and a line cover 19. For reinforcing purposes, provision is made in the fluid lines 4a, 4b, 5a, 5b for a rib structure 21 each, which is preferably supported on the line bottom 18 as well as on the line cover 19.

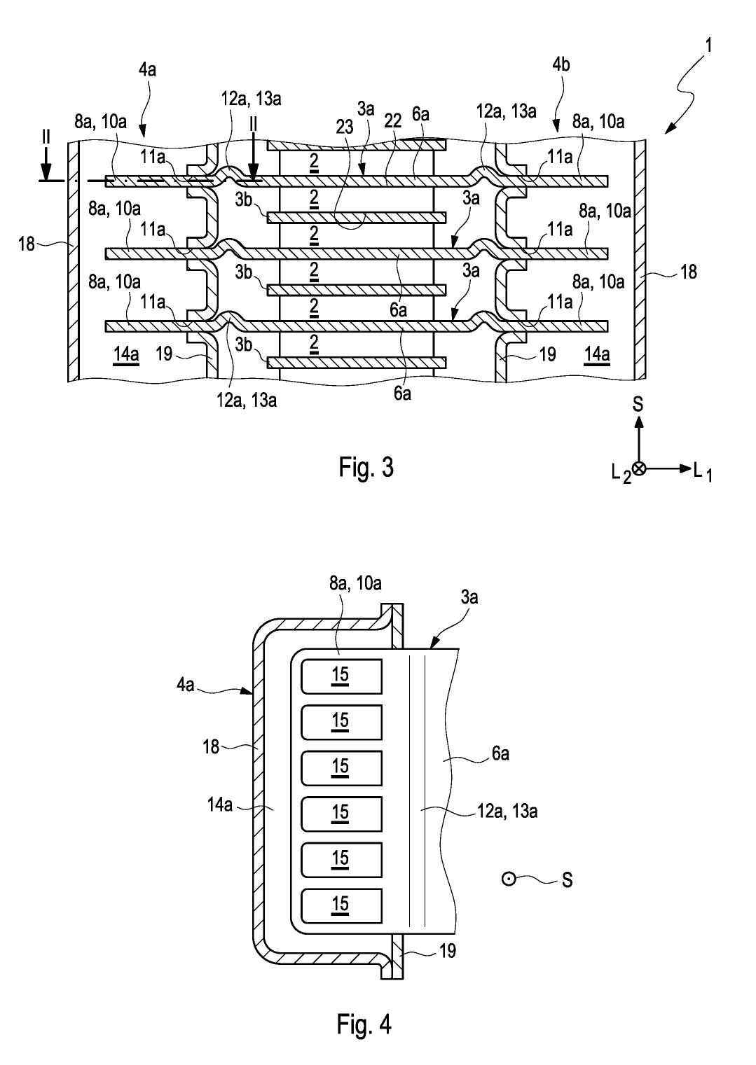

FIG. 3 shows a variation of the example of FIG. 1. In the example of FIG. 3, the end sections of the first sheet-metal shaped parts 3a are embodied as passage sections 10a, which lengthen the main section 6a in its direction of longitudinal extent L₁, and which engage through an aperture 11a, which is provided in the respective first or second fluid line 4a, 4b. The engagement sections 10a, 10b protrude into the fluid lines 4a, 4b, 5a, 5b. In the example of FIG. 3, the first sheet-metal shaped parts 3a are also connected to the respective fluid line 4a, 4b in the area of the apertures 11a by means of an integral connection, preferably by means of a solder connection.

With regard to the engagement sections 10a, 10b, the second sheet-metal shaped parts 3b are embodied in the same way as the first sheet-metal shaped parts 3a (not illustrated in the sectional illustration of FIG. 3). In the transition area between the main section 6a and the end section 8a, the first sheet-metal shaped parts 3a have a bead 12a, which are arranged outside of a line interior 14a of the fluid line 4a and which act on the first sheet-metal shaped part 3a as stop 13a.

FIG. 4 shows the thermoelectric device 1 in a cross section along the section line II-II of FIG. 1. It can be seen that the first sheet-metal shaped part 3a has a number of passage openings 15 in the engagement section 10a.

When now looking at the illustration of FIG. 2 again, it can be seen that the sheet-metal shaped parts 3a, 3b each have two longitudinal sides 16 and two transverse sides, wherein the longitudinal side 16 of a first sheet-metal shaped part 3a extends perpendicular to the longitudinal side 16 of a second sheet-metal shaped part 3b. The two first fluid lines 4a, 4b are arranged on the two longitudinal ends 7a, 7b of the first sheet-metal shaped parts 3a. The two second fluid lines 5a, 5b are arranged on the two longitudinal ends 7a, 7b of the second sheet-metal shaped parts 3b. A longitudinal direction L is defined by the longitudinal sides 16 of the first heat conducting elements 3a. A transverse direction Q is defined by the transverse sides 17 of the first heat conducting elements 3a. The two first fluid lines 4a, 4b lie opposite one another along the longitudinal direction L. The two second fluid lines 5a, 5b lie opposite one another along the transverse direction Q.

In a cross section vertically to the stacking direction S, the first and second fluid lines 4a, 4b, 5a, 5b preferably each have substantially the geometry of a rectangle, wherein a respective fluid line 4a, 4b, 5a, 5b is connected along its longitudinal side 16 to a transverse side 17 of the respective sheet-metal shaped part 3a, 3b. In the cross section vertically to the stacking direction S, the two first fluid lines 4a, 4b are arranged substantially offset by 90° to the two second fluid lines according to FIG. 2. The two first fluid lines 4a, 4b and the two second fluid lines 5a, 5b each extend along the stacking direction S. In the example scenario, the fluid lines 4a, 4b, 5a, 5b are each embodied in two parts with a line bottom 18 and with a line cover 19. The line cover 19 is thereby mechanically and thermally connected to the first or second sheet-metal shaped parts 3a, 3b, respectively.

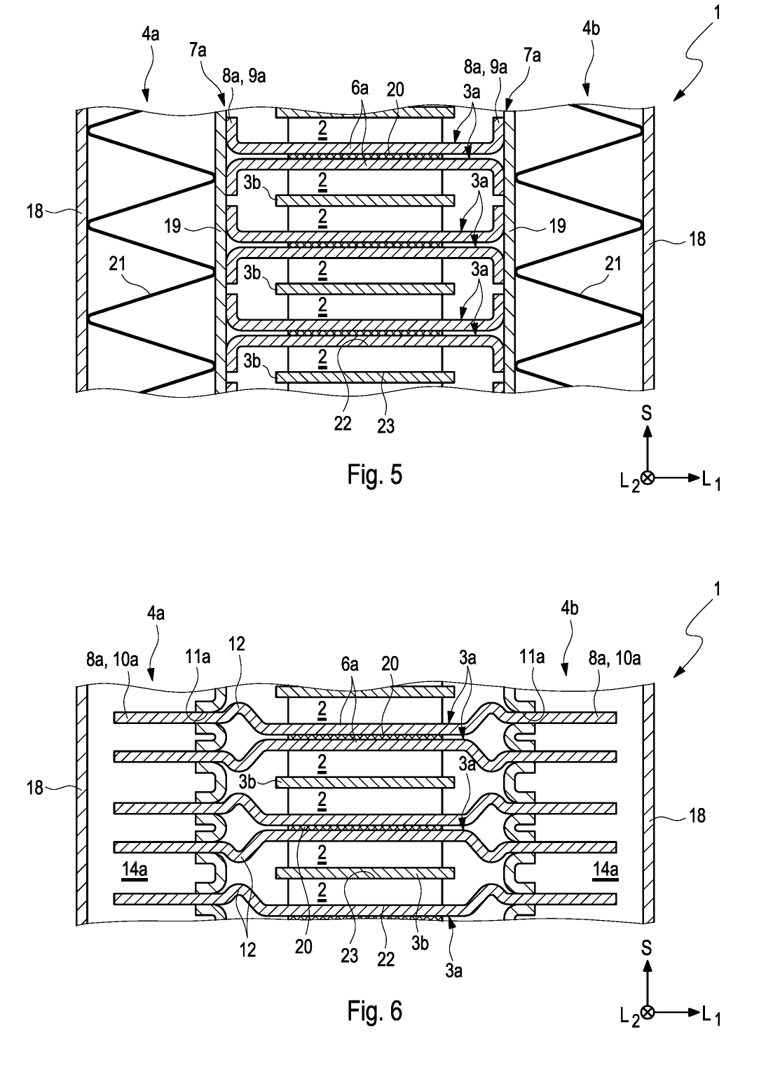

FIG. 5 shows a further variation of the example of FIG. 1. In the case of this variation, first and second sheet-metal shaped parts 3a, 3b are alternately arranged between two thermoelectric modules 2 in an analogous manner. In the example of FIG. 5, however, provision is made between two thermoelectric modules 2 for two first sheet-metal shaped parts 3a instead of an individual first sheet-metal shaped part 3a.

As can be seen in FIG. 5, provision is made between the two adjacent first sheet-metal shaped parts 3a for an intermediate layer 20. Instead of an intermediate layer 20, an intermediate film, preferably of an elastic material, most preferably of graphite, can also be present. However, the intermediate layer 20 can also be forgone, so that the two first sheet-metal shaped parts 3a lie flat against one another in the area of the main sections. In the case of both variations, the collar sections 9a stick out from the main sections 6a in the opposite direction, preferably along the stacking direction S. In a variation of the example of FIG. 5, which is not shown in the Figures, two second sheet-metal shaped parts 3b can also be arranged between two adjacent thermoelectric modules 2i analogously to the two first sheet-metal shaped parts 3a. An intermediate layer 20 or an intermediate film can be arranged between the two adjacent first sheet-metal shaped parts 3a.

Finally, FIG. 6 shows a combination of the variations of FIGS. 3 and 5 in an exemplary manner. The first sheet-metal shaped parts 3a arranged between two adjacent thermoelectric modules 2 are thus not provided with collar sections, as in the case of the example of FIG. 5, but, analogously to the example of FIG. 5, with engagement sections 10a, which engage through apertures 11a, which are present on the first fluid lines 3a. The two first sheet-metal shaped parts 3a can be equipped with beads 12a analogous to the example of FIG. 3.

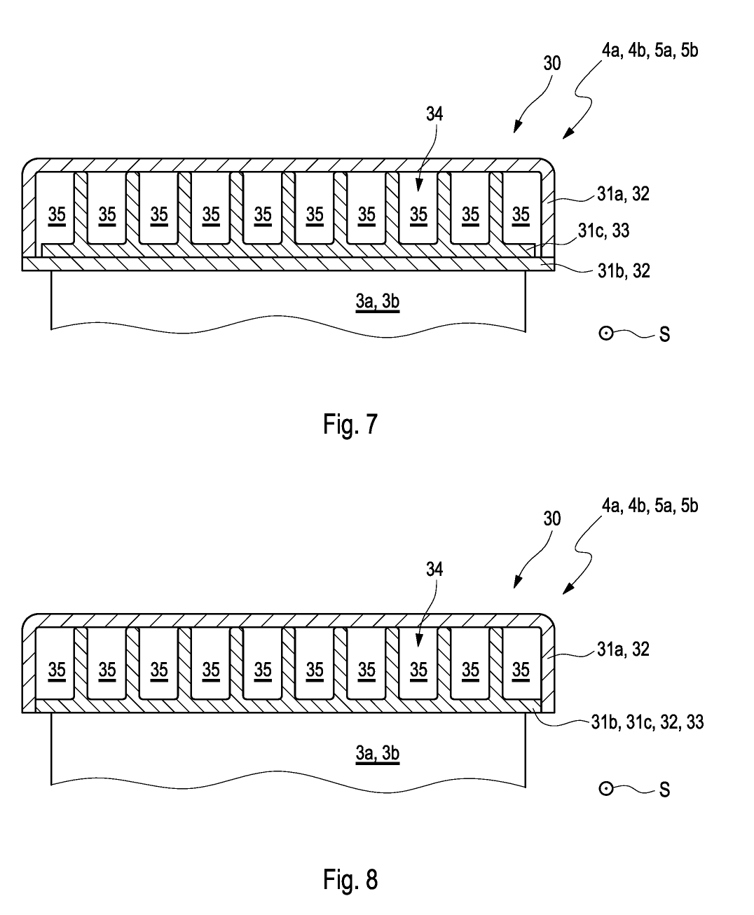

FIG. 7 shows a further development of a first or second fluid line 4a, 4b, 5a, 5b in a cross section vertically to the stacking direction S. It can be seen that the fluid line 4a, 4b, 5a, 5b is embodied as three-part flat pipe 30 comprising a first and a second part 31a, 31b, which together form an outer structure 32. The two parts 31a, 31b can be welded or soldered to one another. The outer structure 32 defines an interior 34 of the flat pipe 30. A third part 31c of the flat pipe 30 forms a rib-like inner structure 33, which divides the interior 34 into multiple fluid channels 35 and which is supported on the outer structure 32 for reinforcing the flat pipe 30. The inner structure 33 can be welded or soldered to the outer structure 32.

As shown in FIG. 7, the first part 31a can be embodied as housing cover and the second part 31b as housing bottom, or vice versa (not illustrated in FIG. 7).

FIG. 8 shows a variation of the example of FIG. 7, in which the third part 31c, which forms the inner structure 33, is integrally molded on the second part 31b of the outer structure 32. In the example of FIG. 8, the flat pipe 30 is thus embodied in two parts.

1. A thermoelectric device comprising:
a plurality of thermoelectric modules stacked one atop the other along a stacking direction each having a plurality of thermoelectric elements;
a plurality of elongated first sheet-metal shaped parts extending along a first direction of longitudinal extent and thermally coupling the plurality of thermoelectric modules to two first fluid lines, the plurality of first sheet-metal shaped parts thermally and mechanically coupled to the plurality of thermoelectric modules; and
a plurality of elongated second sheet-metal shaped parts extending along a second direction of longitudinal extent and thermally coupling the plurality of thermoelectric modules to two second fluid lines, the second direction of longitudinal extent extending perpendicular to the first direction of longitudinal extent;
wherein each of the plurality of first sheet-metal shaped parts and each of the plurality of second sheet-metal shaped parts have a respective main section disposed between two respective longitudinal ends, the respective main section transitioning into a respective end section at the two respective longitudinal ends, the respective end section thermally and mechanically connected to an associated fluid line of the two first fluid lines and the two second fluid lines.

2. The thermoelectric device according to claim 1, wherein the respective end section is structured as a collar section projecting at an angle from the respective main section.

3. The thermoelectric device according to claim 2, wherein the collar sections extends from the respective main section along the stacking direction.

4. The thermoelectric device according to claim 2, wherein the collar section projects from the respective main section at a right angle.

5. The thermoelectric device according to claim 1, wherein one of i) a first sheet-metal shaped part of the plurality of first sheet-metal shaped parts and ii) a second sheet-metal shaped part of the plurality of second sheet-metal shaped parts is arranged in the stacking direction between two adjacent thermoelectric modules of the plurality of thermoelectric modules, the first sheet-metal shaped part mechanically and thermally connected to the two first fluid lines, and the second sheet-metal shaped part mechanically and thermally connected to the two second fluid lines.

6. The thermoelectric device according to claim 1, wherein at least one of i) two first sheet-metal shaped parts of the plurality of first sheet-metal shaped parts and ii) two second sheet-metal shaped parts of the plurality of second sheet-metal shaped parts are arranged in the stacking direction between two adjacent thermoelectric modules of the plurality of thermoelectric modules.

7. The thermoelectric device according to claim 6, wherein, in an area of the respective main section, the at least one of i) the two first sheet-metal shaped parts and ii) the two second sheet-metal shaped parts lie flat against one another.

8. The thermoelectric device according to claim 6, wherein the respective end section is structured as a collar section projecting at an angle from the respective main section, and wherein the collar sections of the at least one of i) the two first sheet-metal shaped parts and ii) the two second sheet-metal shaped parts project from the respective main section in opposite directions.

9. The thermoelectric device according to claim 6, wherein at least one of an intermediate layer and an intermediate film is arranged between the at least one of i) the two first sheet-metal shaped parts and ii) the two second sheet-metal shaped parts.

10. The thermoelectric device according to claim 1, wherein at least one of i) a first sheet-metal shaped part of the plurality of first sheet-metal shaped parts and ii) a second sheet-metal shaped part of the plurality of second sheet-metal shaped parts is coupled to at least one fluid line of the two first fluid lines and the two second fluid lines via an integral connection.

11. The thermoelectric device according to claim 1, wherein at least one of i) a first sheet-metal shaped part of the plurality of first sheet-metal shaped parts and ii) a second sheet-metal shaped part of the plurality of second sheet-metal shaped parts is coupled to at least one fluid line of the two first fluid lines and the two second fluid lines via at least one of a thermally conducting layer and a thermally conducting film.

12. The thermoelectric device according to claim 1, wherein the respective end section is structured as an engagement section, the engagement section lengthening the respective main section of the plurality of first sheet-metal shaped parts in the first direction of longitudinal extent and engaging through an aperture of an associated first fluid line of the two first fluid lines such that the engagement section protrudes into a line interior of the associated first fluid line, the engagement section lengthening the respective main section of the plurality of second sheet-metal shaped parts in the second direction of longitudinal extent and engaging through an aperture of an associated second fluid line of the two second fluid lines such that the engagement section protrudes into a line interior of the associated second fluid line.

13. The thermoelectric device according to claim 12, wherein at least one of the plurality of first sheet-metal shaped parts and the plurality of second sheet-metal shaped parts is connected to the associated first fluid line and the associated second fluid line, respectively, in an area of the aperture via an integral connection.

14. The thermoelectric device according to claim 12, wherein, in a transition area between the respective main section and the respective end section, at least one of the plurality of first sheet-metal shaped parts and the plurality of second sheet-metal shaped parts includes at least one bead arranged outside of the line interior of the associated first fluid line and the line interior of the associated second fluid line, respectively, and wherein the at least one bead is configured as a stop.

15. The thermoelectric device according to claim 12, wherein the engagement section of at least one of the plurality of first sheet-metal shaped parts and the plurality of second sheet-metal shaped parts includes at least one passage opening.

16. The thermoelectric device according to claim 1, wherein at least one of i) a first fluid line of the two first fluid lines and ii) a second fluid line of the two second fluid lines includes a line bottom and a line cover, and wherein a reinforcing rib structure is arranged in at least one of the two first fluid lines and the two second fluid lines.

17. The thermoelectric device according to claim 1, wherein the plurality of first sheet-metal shaped parts and the plurality of second sheet-metal shaped parts are arranged in an alternating manner along the stacking direction.

18. The thermoelectric device according to claim 1, wherein the plurality of first sheet-metal shaped parts and the plurality of second sheet-metal shaped parts each have two longitudinal sides and two transverse sides, and wherein a longitudinal side of the two longitudinal sides of a first sheet-metal shaped part of the plurality of first sheet-metal shaped parts extends perpendicular to a longitudinal side of the two longitudinal sides of a second sheet-metal shaped part of the plurality of second sheet-metal shaped parts.

19. The thermoelectric device according to claim 1, wherein the two first fluid lines are arranged on the two respective longitudinal ends of the plurality of first sheet-metal shaped parts and the two second fluid lines are arranged on the two respective longitudinal ends of the plurality of second sheet-metal shaped parts.

20. The thermoelectric device according to claim 1, wherein in a cross section perpendicular to the stacking direction the two first fluid lines are arranged substantially offset by 90° relative to the two second fluid lines.

21. The thermoelectric device according to claim 1, wherein:
at least one of the two first fluid lines and the two second fluid lines is structured as a three-part flat pipe including a first part, a second part, and a third part;
the first part and the second part form an outer structure defining an interior of the flat pipe; and
the third part forms a rib-like inner structure dividing the interior into a plurality of fluid channels and is supported on the outer structure such that the third part reinforces the flat pipe.

22. The thermoelectric device according to claim 1, wherein:
at least one of two first fluid lines and the two second fluid lines is structured as a two-part flat pipe including a first part and a second part, the first part and the second part forming an outer structure defining an interior of the flat pipe; and
the flat pipe includes a third part integrally molded on the second part, the third part forming a rib-like inner structure, dividing the interior into a plurality of fluid channels, and supported on the outer structure such that the third part reinforces the flat pipe.
